(19) United States
(12) Patent Application Publication
(10) Pub. No.: US 2026/0239791 A1
(43) Pub. Date: Aug. 13, 2026

(54) LIGHT-EMITTING APPARATUS AND METHOD OF ASSEMBLING LIGHT-EMITTING APPARATUS

(71) Applicant: STANLEY ELECTRIC CO., LTD., Tokyo (JP)

(72) Inventor: Takuji UMEZU, Tokyo (JP)

(73) Assignee: STANLEY ELECTRIC CO., LTD., Tokyo (JP)

(21) Appl. No.: 19/535,096

(22) Filed: Feb. 10, 2026

(30) Foreign Application Priority Data
Feb. 12, 2025 (JP) 2025-021064

(51) Int. Cl. H10H 20/858; H10H 20/01; H10H 20/84

(52) U.S. Cl. CPC H10H 20/8582; H10H 20/034; H10H 20/0365; H10H 20/84

(57) ABSTRACT

There are provided a light-emitting apparatus and a method of assembling the light-emitting apparatus capable of more efficiently dissipating heat, which is generated by a semiconductor light-emitting chip, from a base to a holder. The light-emitting apparatus includes: a package including a base, a cap that is mounted on an upper surface of the base, and a semiconductor light-emitting chip disposed in the cap; and a holder that holds the package. The holder has a through-hole into which the package is inserted and a cylindrical portion disposed around an opening of the through-hole on the upper surface of the holder. The cylindrical portion covers at least a part of an outer circumferential surface of the cap of the package inserted into the through-hole. An inner wall surface of the through-hole has a step. A first gap portion is provided between the step and the upper surface of the base on which the cap is not mounted. A second gap portion continuous with the first gap portion is provided between an inner wall surface of the cylindrical portion and the outer circumferential surface of the cap. A thermally conductive gel having a higher thermal conductivity than air fills the first gap portion and the second gap portion.

### BACKGROUND OF THE INVENTION

### 1. Field of the Invention

The present disclosure relates to a light-emitting apparatus and a method of assembling the light-emitting apparatus.

### 2. Description of Related Art

Light-emitting apparatuses equipped with semiconductor light-emitting chips using light sources such as laser diodes (LDs) and light-emission diodes (LEDs) are used in various fields such as medicine and industry.

An example of a structure of a light-emitting apparatus is PTL 1. PTL 1 describes a laser light-emitting apparatus including: a laser package that includes a metal stem on which the LD is mounted, and a terminal electrically connected to the stem; a metal heat sink that receives heat from the laser package; and an insulating heat-conducting member (elastic material) that is disposed between the heat sink and the stem and electrically insulates the heat sink from the stem and transfers heat from the stem to the heat sink.

Examples of related art includes JP2017-84939A.

### SUMMARY OF THE INVENTION

In the light-emitting apparatus described in PTL 1,heat generated by the semiconductor light-emitting chip is transferred to the heat sink by bringing a part of the lower surface and a part of the side surface of the stem (base) into contact with the heat sink (holder) directly or with an insulating thermally conductive member interposed therebetween.

According to the structure of the light-emitting apparatus, a substrate made of a material having a low thermal conductivity may be disposed on the lower surface of the stem instead of the heat sink or the insulating thermally conductive member. In such cases, it is necessary to bring the side surface of the stem into contact with the heat sink to conduct heat from the stem to the heat sink. However, since a contact area between the heat sink and the side surface of the stem is limited, heat is unlikely to be efficiently dissipated only from the side surface of the stem.

Meanwhile, there is a manufacturing error in a positional relationship between the stem and other components constituting the package mounted on the stem. For this reason, when the heat sink is processed such that the side surface of the stem is brought into contact with the heat sink, a clearance to allow for manufacturing errors must be provided between the side surface of the other component and the heat sink. Therefore, it is difficult to process the heat sink such that both the side surface of the stem and the side surface of the other component are brought into contact with the heat sink.

According to the present disclosure, it is desired to provide a light-emitting apparatus and a method of assembling the light-emitting apparatus capable of more efficiently transferring heat generated by the semiconductor light-emitting chip from the base to the holder.

According to one aspect of the present disclosure, a light-emitting apparatus includes: a package including a base, a cap, and a semiconductor light-emitting chip disposed in the cap; and a holder that holds the package. The holder has a through-hole into which the package is inserted and a cylindrical portion disposed around an opening of the through-hole on the upper surface of the holder, and the cylindrical portion covers at least a part of an outer circumference of the cap of the package inserted into the through-hole. A first gap portion is provided between the holder and the cap. A second gap portion continuous with the first gap portion is provided between an inner wall surface of the cylindrical portion and the outer circumferential surface of the cap. A thermally conductive gel having a higher thermal conductivity than air fills the first gap portion and the second gap portion.

According to another aspect of the present disclosure, a method of assembling the above-mentioned light-emitting apparatus includes: placing an annular thermally conductive gel sheet made of the thermally conductive gel on an inner wall surface of the holder; and inserting the package into the through-hole of the holder, bringing the thermally conductive gel sheet into contact with a step of the holder and pressing the thermally conductive gel sheet to deform the thermally conductive gel, and filling the gap portions with the thermally conductive gel.

According to each aspect of the present disclosure, the second gap portion is provided. Therefore, the thermally conductive gel having a higher thermal conductivity than air reliably fills the first gap portion between the holder and the upper surface of the base on which the cap is not mounted. Thereby, not only the side surface of the base but also the upper surface (on which the cap is not mounted) is in contact with the holder with the thermally conductive gel interposed therebetween, ensuring a heat dissipation path from the base to the holder. As a result, it is possible to more efficiently transfer heat, which is generated by the semiconductor light-emitting chip, from the base to the holder.

### BRIEF DESCRIPTION OF THE DRAWINGS

FIG. 1 is a schematic cross-sectional view of a light-emitting apparatus according to a first embodiment.

FIG. 2 is an enlarged cross-sectional view of a part of a base, a cap, a holder, and a thermally conductive gel shown in FIG. 1.

FIG. 3A is a cross-sectional view of a package and a substrate in a first process of a method of assembling the light-emitting apparatus according to the first embodiment.

FIG. 3B is a cross-sectional view of the holder and a thermally conductive gel sheet in a second process of the method of assembling the light-emitting apparatus according to the first embodiment. FIG. 3C is a cross-sectional view of the package, the substrate, the holder, and the thermally conductive gel sheet in a third process of the method of assembling the light-emitting apparatus according to the first embodiment. FIG. 3D is a cross-sectional view of the light-emitting apparatus after the third process is performed.

FIG. 4 is a perspective view of the thermally conductive gel sheet.

FIG. 5 is a schematic cross-sectional view of a light-emitting apparatus according to a second embodiment.

FIG. 6 is an enlarged cross-sectional view of a part of a base, a cap, a holder, and a thermally conductive gel of FIG. 5.

FIG. 7 is an enlarged cross-sectional view of a part of the base, the cap, the holder, and the thermally conductive gel of the light-emitting apparatus according to the second embodiment.

### DESCRIPTION OF EMBODIMENTS

Hereinafter, the light-emitting apparatus according to the present embodiment will be described in detail with reference to the drawings. It should be noted that the terms “upper surface” and “lower surface” used in the present specification may be reversed.

### First Embodiment

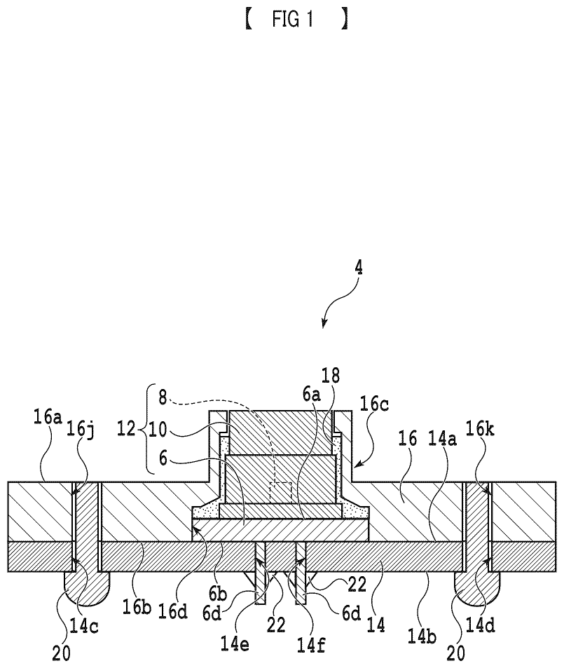

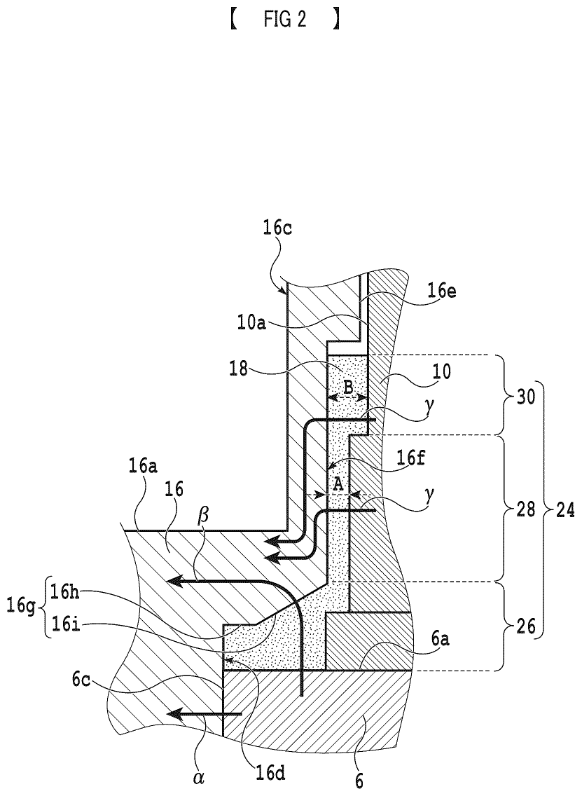

FIG. 1 is a schematic cross-sectional view of a light-emitting apparatus 4 according to the first embodiment. FIG. 2 is an enlarged cross-sectional view of a part of a base 6, a cap 10, a holder 16, and a thermally conductive gel 18 shown in FIG. 1. As shown in FIGS. 1 and 2, the light-emitting apparatus 4 includes the base 6. The base 6 is a disc-shaped member made of brass, and has a circular upper surface 6a, a circular lower surface 6b parallel to the upper surface 6a, and a side surface 6c between the upper surface 6a and the lower surface 6b. The base 6 has leads 6d each of which penetrates the base 6 from the upper surface 6a to the lower surface 6b. The leads 6d and the base 6 are insulated by an insulating material such as ceramic. However, a material and a shape of the base 6 are not limited thereto.

A semiconductor light-emitting chip 8 is mounted on the upper surface 6a of the base 6. In the present embodiment, an LD chip is used as the semiconductor light-emitting chip 8. The semiconductor light-emitting chip 8 is not limited to the LD chip. The semiconductor light-emitting chip 8 is electrically connected to the base 6 and to an external terminal (not shown in the drawing) of the light-emitting apparatus 4 via the leads 6d.

The cap 10 is mounted on the upper surface 6a of the base 6 to cover the outer circumference of the semiconductor light-emitting chip 8. The cap 10 is a cylindrical member made of stainless steel or the like, and has a diameter (width) less than a diameter of the base 6. The cap 10 is configured such that a plurality of cylindrical members having different diameters are stacked and connected in the vertical direction and the diameter of the cap 10 decreases from the lower side (the side of the base 6) to the upper side (the side opposite to the base 6). However, a material and a shape of the cap 10 are not limited thereto.

A lower part of the cap 10 (the side of the base 6) is fixed onto the upper surface 6a of the base 6. A lens (not shown in the drawing), which transmits the laser beam generated by the semiconductor light-emitting chip 8, is provided on the upper part of the cap 10 (the side opposite to the base 6).

A package (laser diode package) 12 is configured with the base 6, the semiconductor light-emitting chip 8, and the cap 10 described above. The package having the shape is generally referred to as a CAN-type package.

The light-emitting apparatus 4 has a substrate (mounting substrate) 14. The substrate 14 is made of a resin material, such as a flame retardant type 4 (FR4), and is a disk-shaped member having a circular upper surface 14a and a circular lower surface 14b parallel to the upper surface 14a. However, a material and a shape of the substrate 14 are not limited thereto.

Through-holes 14c and 14d penetrating the substrate 14 in the thickness direction are provided at the end portions of the substrate 14. Further, through-holes 14e and 14f penetrating the substrate 14 in the thickness direction are provided in a part including the substantially center of the substrate 14. Leads 6e of the base 6 are inserted into the through-holes 14e and 14f.

The holder 16 is mounted on the upper surface 14a of the substrate 14. The holder 16 is made of a material with high thermal conductivity to function as a heat dissipation member (heat sink) for dissipating heat from the semiconductor light-emitting chip 8 to the outside. A specific example of a material of the holder 16 is aluminum. However, a material of the holder 16 is not limited thereto.

The holder 16 is a disk-shaped member having a circular upper surface 16a and a lower surface 16b parallel to the upper surface 16a. A through-hole 16d penetrating the holder 16 in the thickness direction is provided in the part including the center of the holder 16. A cylindrical portion 16c is provided around an opening 16e of the through-hole 16d on the upper surface 16a of the holder 16. An inner wall surface 16f of the holder 16 is formed by an inner wall surface of the cylindrical portion 16c and an inner wall surface of a part of the through-hole 16d (an inner wall surface of the through-hole 16d).

A diameter (width) of the through-hole 16d in the holder 16 is set such that the inner wall surface 16f of the through-hole 16d is in contact with the side surface 6c of the base 6. The holder 16 and the side surface 6c of the base 6 are in contact. Therefore, heat generated by the semiconductor light-emitting chip 8 is directly transferred from the base 6 to the holder 16 (first heat dissipation path α, refer to FIG. 2). It is desirable that the contact between the holder 16 and the side surface 6c of the base 6 is perfect. However, as long as a certain amount of contact area is ensured, the function of the first heat dissipation path α is satisfactory, and thus partial contact therebetween is also possible.

The inner diameter of the cylindrical portion 16c is less than the diameter of the through-hole 16d and greater than the outer diameter of the cap 10. The cap 10 is disposed in the cylindrical portion 16c such that an outer circumferential surface 10a of the cap 10 is covered by the inner wall surface 16f of the cylindrical portion 16c.

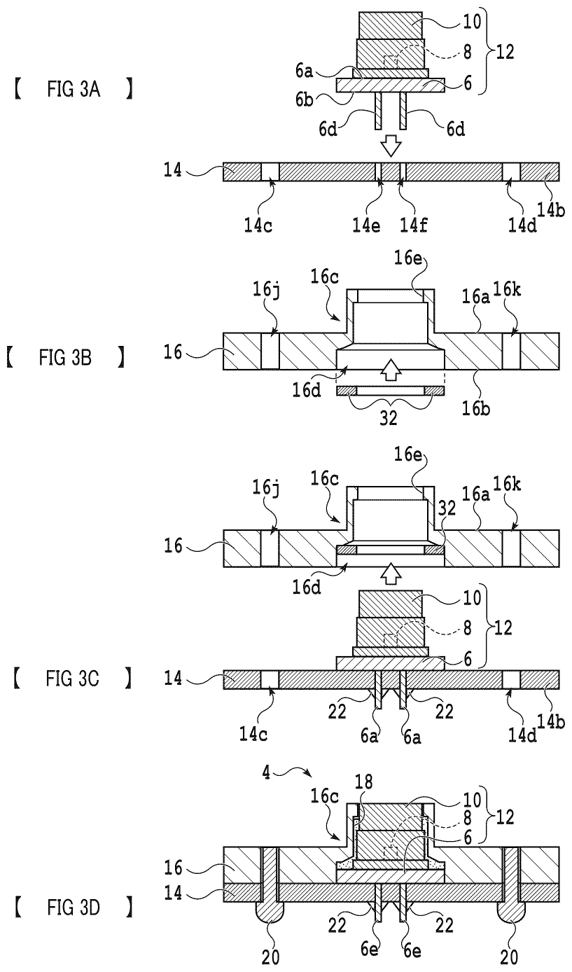

As shown in FIGS. 3A to 3D, a step 16g is provided on the inner wall surface 16f between the cylindrical portion 16c of the holder 16 and the through-hole 16d. The step 16g has a first surface 16h parallel to the upper surface 16a of the holder 16, and a second surface 16i that is continuous with the first surface 16h and is inclined such that a distance from the upper surface 6a of the base 6 is larger at a position closer to the outer circumferential surface 10a of the cap 10. A first gap portion 26 is formed between the upper surface 6a of the base 6 and the second surface 16i of the inner wall surface 16f of the holder 16.

A second gap portion 28 is formed above the step 16g of the holder 16 (toward the opening 16e) between the outer circumferential surface 10a of the cap 10 and the inner wall surface 16f of the holder 16. The first gap portion 26 and the second gap portion 28 are continuous.

A third gap portion 30 is formed, above the second gap portion 28 of the holder 16 (toward the opening 16e), between the outer circumferential surface 10a of the cap 10 and the inner wall surface 16f of the holder 16. The third gap portion 30 and the second gap portion 28 are continuous. A distance B between the inner wall surface 16f of the holder 16 and the outer circumferential surface 10a of the cap 10 in the third gap portion 30 is greater than a distance A between the inner wall surface 16f of the holder 16 and the outer circumferential surface 10a of the cap 10 in the second gap portion 28.

The thermally conductive gel 18 fills the first gap portion 26 and the second gap portion 28. Thereby, a part of the upper surface 6a of the base 6 on which the cap 10 is not mounted is in contact with the holder 16 with the thermally conductive gel 18 interposed therebetween. Therefore, heat generated by the semiconductor light-emitting chip 8 is transferred from the base 6 to the holder 16 via the thermally conductive gel 18 (second heat dissipation path β, refer to FIG. 2). The thermally conductive gel 18 also fills at least a part of the third gap portion 30. A material and a detailed structure of the thermally conductive gel 18 will be described later.

As shown in FIG. 1, through-holes 16j and 16k that penetrate the holder 16 in the thickness direction are provided in the end portion of the holder 16 on the outer circumferential side thereof. Screws 20 are inserted into the through-hole 16j of the holder 16 and the through-hole 14c of the substrate 14. Further, the screws 20 are inserted into the through-hole 16k of the holder 16 and the through-hole 14d of the substrate 14. The screws 20 fixes the holder 16 to the substrate 14.

Solders 22 are fixed on the leading end portions of the leads 6e inserted into the through-hole 14c of the substrate 14. The solders 22 fix the leads 6d onto the substrate 14, along with an external terminal (not shown in the drawing) of the light-emitting apparatus 4.

Next, a method of assembling the light-emitting apparatus 4 described above will be described. FIG. 3A is a cross-sectional view of the package 12 and the substrate 14 in a first process of the method of assembling the light-emitting apparatus 4 according to the first embodiment. FIG. 3B is a cross-sectional view of the holder 16 and a thermally conductive gel sheet 32 in a second process of the method of assembling the light-emitting apparatus 4 according to the first embodiment. FIG. 3C is a cross-sectional view of the package 12, the substrate 14, the holder 16, and the thermally conductive gel sheet 32 in a third process of the method of assembling the light-emitting apparatus 4 according to the first embodiment. FIG. 3D is a cross-sectional view of the light-emitting apparatus 4 after the third process is performed.

As shown in FIG. 3A, in the first process of the method of assembling the light-emitting apparatus 4 according to the first embodiment, the package 12 and the substrate 14 are assembled. Specifically, the base 6 and the substrate 14 are brought relatively close to each other, and the leads 6d of the base 6 are inserted into the through-holes 14e and 14f of the substrate 14, thereby bringing the upper surface 14a of the substrate 14 into contact with the lower surface 6b of the base 6. Thereby, a set including the package 12 and the substrate 14 is formed.

Next, in the second process, as shown in FIG. 3B, the thermally conductive gel sheet 32 is placed on the step 16g (refer to FIG. 2) of the holder 16. As a result, a set including the holder 16 and the thermally conductive gel sheet 32 is formed.

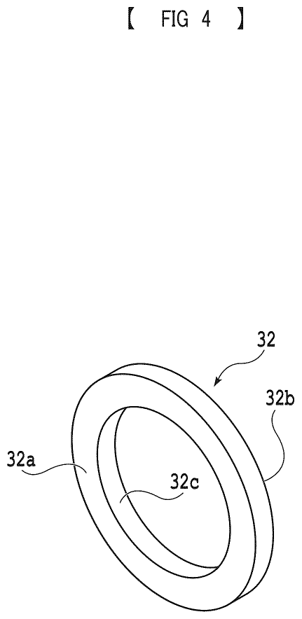

FIG. 4 is a perspective view of the thermally conductive gel sheet 32. As shown in FIG. 4, the thermally conductive gel sheet 32 is an annular member having a circular first surface 32a and a second surface 32b parallel to the first surface 32a, and has an opening portion 32c that is open to the first surface 32a and the second surface 32b.

A diameter (width) of the thermally conductive gel sheet 32 is equal to a diameter (width) of the base 6. A diameter (width) of the opening portion 32c is equal to a diameter (width) of the cap 10. However, the shape and the size of the thermally conductive gel sheet 32 are not limited thereto. It should be noted that either of the first and second processes may be performed first.

As shown in FIG. 3C, in the third process, the set including the package 12 and the substrate 14 and the set including the holder 16 and the thermally conductive gel sheet 32 are aligned such that the cap 10 is inserted into the through-hole 16d of the holder 16. Then, the set including the package 12 and the substrate 14 and the set including the holder 16 and the thermally conductive gel sheet 32 are brought relatively close to each other.

In such a case, after the upper surface 6a of the base 6 and the thermally conductive gel sheet 32 come into contact, the first member, such as the holder 16, and the second member, such as the package 12, are brought relatively close to each other. Then, the upper surface 6a of the base 6 presses the thermally conductive gel sheet 32 toward the step 16g. For example, the second member may be fixed, and by pressing the first member which is mounted on a machine capable of a pressing operation (not shown in the drawing), the first member may be fitted onto the second member from above. Simultaneously, the thermally conductive gel sheet 32 is pulled by the outer circumferential surface 10a of the cap 10 and enters the inside of the cylindrical portion 16c.

The thermally conductive gel sheet 32 is deformed by being pressed by the upper surface 6a of the base 6 and being simultaneously pulled by the outer circumferential surface 10a of the cap 10. Accordingly, the thermally conductive gel 18 constituting the thermally conductive gel sheet 32 expands (spreads) along the inner wall surface 16f of the through-hole 16d. In such a case, the second surface 16i is inclined, and thus guides the thermally conductive gel 18 such that the thermally conductive gel 18 is likely to expand from the first gap portion 26 to the second gap portion 28. Then, the thermally conductive gel 18 fills the first gap portion 26 and the second gap portion 28.

By filling the first gap portion 26 and the second gap portion 28 with the thermally conductive gel 18, the upper surface 6a of the base 6, on which the cap 10 is not mounted, comes into contact with the step 16g of the holder 16 with the thermally conductive gel 18 interposed therebetween. Thereby, the heat generated from the base 6 is transferred from the upper surface 6a of the base 6 to the holder 16 via the thermally conductive gel 18 (second heat dissipation path β). Further, the heat generated from the cap 10 is transferred from the outer circumferential surface 10a of the cap 10 to the holder 16 via the thermally conductive gel 18 and the cylindrical portion 16c (third heat dissipation path γ).

That is, in the present embodiment, the heat can be transferred to the holder 16 not only from the side surface 6c of the base 6, but also from the upper surface 6a of the base 6 and the outer circumferential surface 10a of the cap 10.

The distance B between the inner wall surface 16f of the holder 16 and the outer circumferential surface 10a of the cap 10 in the third gap portion 30 is greater than the distance A between the inner wall surface 16f of the holder 16 and the outer circumferential surface 10a of the cap 10 in the second gap portion 28. Thereby, the thermally conductive gel 18 can sufficiently fill the first gap portion 26 and the second gap portion 28, and the expansion of the upper end of the thermally conductive gel 18 can be confined within the third gap portion 30. Thereby, the thermally conductive gel 18 is prevented from protruding outside the holder 16, preventing defects from being caused in the appearance of the product.

From the perspective of dissipating the heat generated from the base 6 from the thermally conductive gel 18, it is preferable that the thermal conductivity of the thermally conductive gel 18 is 1 W/mK or greater. If the thermal conductivity of the thermally conductive gel 18 is less than 1 W/mK, the heat will not be efficiently dissipated from the base 6 to the holder 16. The thermal conductivities described in the present specification are values measured on the basis of American society for testing and materials (ASTM) D5470 or Japanese industrial standard (JIS) R2616.

The hardness of the thermally conductive gel 18 is preferably in a range of 5 to 85, and more preferably in a range of 50 to 70, in units of the Shore OO. Alternatively, the hardness of the thermally conductive gel 18 is preferably 60 or greater in units of the Shore OOO (since the Shore OOO cannot express an upper limit, the Shore OO85 is set as the upper limit). It should be noted that the Shore OO and the Shore OOO in the present specification are values evaluated using the test methods prescribed by ASTM D2240 or JIS Z 2246:2000.

If the thermally conductive gel 18 has a hardness of 5 or more and 85 or less in units of the Shore OO, the thermally conductive gel 18 flexibly follows shapes of the upper surface 6a of the base 6, the outer circumferential surface 10a of the cap 10, and the inner wall surface 16f of the through-hole 16d of the holder 16. As a result, the thermally conductive gel 18 is likely to fill the first gap portion 26 and the second gap portion 28. On the other hand, if the thermally conductive gel 18 has a hardness of less than 5 in units of the Shore OO or less than 60 in units of the Shore OOO, the thermally conductive gel 18 becomes excessively fluid. As a result, it is difficult to handle the thermally conductive gel 18.

If the thermally conductive gel 18 has a hardness greater than 85 in units of the Shore OO, the thermally conductive gel 18 is less likely to spread along the upper surface 6a of the base 6, the outer circumferential surface 10a of the cap 10, and the inner wall surface 16f of the through-hole 16d of the holder 16. When tightening the screws 20, reaction force of the gel may be excessively strong, the holder 16 and the substrate 14 may not be completely in tight contact with each other and may have a gap portion.

An example of a material, which satisfies the above-mentioned thermal conductivity ranges and hardness, includes the Lambdagel (registered trademark) COH series (model number: COH-4000 LVC) manufactured by Taica Corporation. The product has a thickness of 1 mm, a hardness of 62 in units of Shore OO, and a thermal conductivity of 2.3 W/mK.

The thickness of the thermally conductive gel sheet 32 is preferably equal to or greater than a thickness of the step 16g. When the thermally conductive gel sheet 32 is made to be equal to or greater than the thickness of the step 16g, the thermally conductive gel 18 can sufficiently fill the first gap portion 26 and the second gap portion 28.

After the above-mentioned third process, as shown in FIG. 3D, the screw 20 is inserted into the through-holes 16j and 14c, and the screw 20 is inserted into the through-holes 16k and 14d. As a result, the light-emitting apparatus 4 is assembled through the fixing of the screws 20.

As described above, according to the present embodiment, as the heat dissipation paths for heat generated from the semiconductor light-emitting chip 8, a first heat dissipation path α (refer to FIG. 2), a second heat dissipation path β (refer to FIG. 2) and a third heat dissipation path γ (refer to FIG. 2) can be ensured. Through the first heat dissipation path α, the heat is transferred from the side surface 6c of the base 6 to the holder 16. Through the second heat dissipation path β, the heat is transferred from the upper surface 6a of the base 6 to the holder 16 via the thermally conductive gel 18. Through the third heat dissipation path γ, the heat is transferred from the outer circumferential surface 10a of the cap 10 to the holder 16 via the thermally conductive gel 18.

Therefore, even if the substrate 14 is made of a material such as resin with low thermal conductivity and heat is less likely to be dissipated from the substrate 14 side, by ensuring the above three heat dissipation paths α, β, and γ, the heat generated by the semiconductor light-emitting chip 8 can be more efficiently transferred from the base 6 to the holder 16.

### Second Embodiment

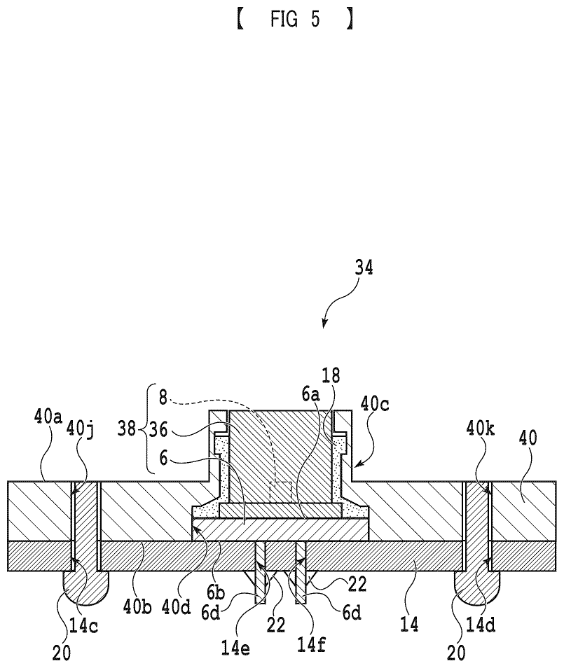

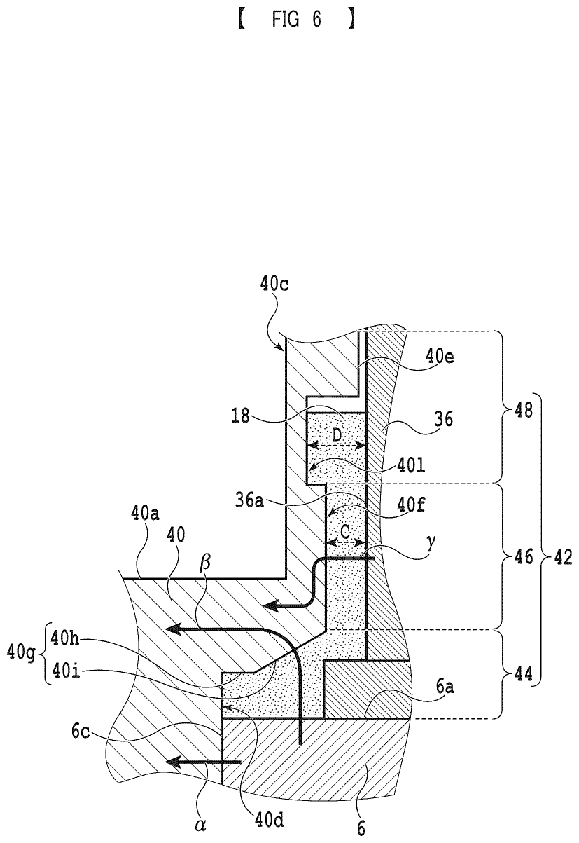

FIG. 5 is a schematic cross-sectional view of a light-emitting apparatus 34 according to a second embodiment. FIG. 6 is an enlarged cross-sectional view of a part of a cap 36, the base 6, a holder 40, and the thermally conductive gel 18 shown in FIG. 5. As shown in FIGS. 5 and 6, a configuration of the light-emitting apparatus 34 according to the second embodiment differs from that of the first embodiment in the configuration of the cap 36 and holder 40. That is, the cap 36 according to the second embodiment is a single member that has a cylindrical shape and the same diameter in a range from the upper side to the lower side.

An inner wall surface 40f of a through-hole 40d of the holder 40 according to the second embodiment has a recess portion 40l. Thereby, a distance D between the inner wall surface 40f of the holder 40 and an outer circumferential surface 36a of the cap 36 in a third gap portion 48 is greater than a distance C between the inner wall surface 40f of the holder 40 and the outer circumferential surface 36a of the cap 36 in a second gap portion 46. With such a configuration, it is also possible to obtain the same effects as the first embodiment. It should be noted that the other part of the light-emitting apparatus 34 according to the second embodiment is the same as that of the first embodiment.

### Third Embodiment

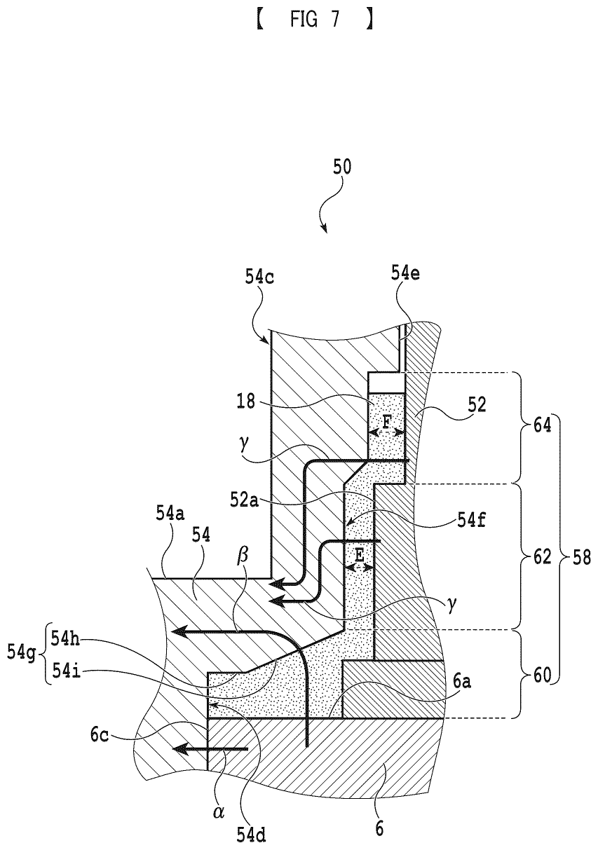

FIG. 7 is an enlarged cross-sectional view of a part of a cap 52, the base 6, a holder 54, and the thermally conductive gel 18 of a light-emitting apparatus 50 according to a third embodiment. As shown in FIG. 7, the configuration of the light-emitting apparatus 50 according to the third embodiment differs from those of the first and second embodiments in that steps are provided in both the cap 52 and the holder 54.

That is, the cap 52 according to the third embodiment has a structure in which a plurality of cylindrical members having different diameters are stacked and connected vertically. The cap 52 is configured such that the diameter of the cap 52 decreases from the lower side (the side of the base 6) toward the upper side (the side opposite to the base 6).

An inner wall surface 54f of a cylindrical portion 54c of the holder 54 according to the third embodiment has steps. Thereby, a distance F between the inner wall surface 54f of the holder 54 and an outer circumferential surface 52a of the cap 52 in a third gap portion 64 is greater than a distance E between the inner wall surface 54f of the holder 54 and the outer circumferential surface 52a of the cap 52 in a second gap portion 62. With such a configuration, it is also possible to obtain the same effects as the first and second embodiments. It should be noted that the other part of the light-emitting apparatus 50 according to the third embodiment is the same as those of the first and second embodiments.

As described above, according to the present embodiment, it is possible to provide a light-emitting apparatus and a method of assembling the light-emitting apparatus capable of more efficiently transferring the heat generated by the semiconductor light-emitting chip from the base to the holder. The light-emitting apparatus according to the present embodiment is used in apparatuses in various fields including medical and industrial applications.

However, the present disclosure is not limited to the above-mentioned embodiments. For example, the light source of the semiconductor light-emitting chip included in the light-emitting apparatus is not limited to the LD described above, and an LED may also be used.

In addition, the structures, methods, and the like according to the above-mentioned embodiments and modification examples may be modified and implemented without departing from the scope of the present disclosure.

What is claimed is:

1. A light-emitting apparatus comprising:
a package including a base, a cap that is mounted on an upper surface of the base and has a diameter less than a diameter of the upper surface of the base, and a semiconductor light-emitting chip disposed in the cap; and
a holder that holds the package,
wherein the holder has a through-hole into which the package is inserted and a cylindrical portion disposed around an opening of the through-hole on the upper surface of the holder, and the cylindrical portion covers at least a part of an outer circumferential surface of the cap of the package inserted into the through-hole,
an inner wall surface of the through-hole has a step, a first gap portion is provided between the step and the upper surface of the base on which the cap is not mounted, and a second gap portion continuous with the first gap portion is provided between an inner wall surface of the cylindrical portion and the outer circumferential surface of the cap, and
a thermally conductive gel having a higher thermal conductivity than air fills the first gap portion and the second gap portion.

2. The light-emitting apparatus according to claim 1, wherein the step has a first surface parallel to the upper surface of the holder and a second surface that is continuous with the first surface and is inclined such that a distance from the upper surface of the base is larger at a position closer to the outer circumferential surface of the cap.

3. The light-emitting apparatus according to claim 1,
wherein a third gap portion continuous with the second gap portion is provided, above the second gap portion, between the inner wall surface of the cylindrical portion and the outer circumferential surface of the cap,
a distance between the inner wall surface of the cylindrical portion and the outer circumferential surface of the cap in the third gap portion is greater than a distance between the inner wall surface of the cylindrical portion and the outer circumferential surface of the cap in the second gap portion, and
the thermally conductive gel fills a part of the third gap portion.

4. The light-emitting apparatus according to claim 1,
wherein the thermally conductive gel has a hardness of 5 or more and 85 or less in units of Shore OO, and
the thermal conductivity of the thermally conductive gel is equal to or greater than 1 W/mK.

5. The light-emitting apparatus according to claim 1,
wherein the base has a lower surface parallel to the upper surface and a side surface provided between the upper surface and the lower surface, and
the side surface is in contact with the inner wall surface of the through-hole.

6. The light-emitting apparatus according to claim 3, wherein a diameter of a part of the cap, in which the outer circumferential surface of the cap faces the third gap portion, is less than a diameter of a part of the cap in which the outer circumferential surface of the cap faces the second gap portion.

7. A method of assembling the light-emitting apparatus according to claim 1, the method comprising:
placing an annular thermally conductive gel sheet made of the thermally conductive gel on an inner wall surface of the holder; and
inserting the package into the through-hole of the holder, bringing the thermally conductive gel sheet into contact with the step and pressing the thermally conductive gel sheet to deform the thermally conductive gel, and filling the first gap portion and the second gap portion with the thermally conductive gel.

8. The method according to claim 7,
wherein the step has a first surface parallel to the upper surface of the holder and a second surface that is continuous with the first surface and is inclined such that a distance from the upper surface of the base is larger at a position closer to the outer circumferential surface of the cap,
the thermally conductive gel is deformed by inserting the package into the through-hole of the holder, bringing the thermally conductive gel sheet into contact with the first surface of the step, and pressing the thermally conductive gel sheet, and
the deformed thermally conductive gel is guided from the first gap portion to the second gap portion via the second surface to fill the second gap portion.
